(19) United States
(12) Patent Application Publication
(10) Pub. No.: US 2024/0120204 A1
(43) Pub. Date: Apr. 11, 2024

(54) SUBSTRATE PROCESSING APPARATUS AND CONTROL METHOD FOR A SUBSTRATE PROCESSING APPARATUS

(71) Applicant: Tokyo Electron Limited, Tokyo (JP)

(72) Inventors: Keisuke TSUGAO, Kumamoto (JP); Yuji TAKIMOTO, Hillsboro, OR (US)

(73) Assignee: Tokyo Electron Limited, Tokyo (JP)

(21) Appl. No.: 17/961,601

(22) Filed: Oct. 7, 2022

(51) Int. Cl. H01L 21/306; C23C 16/44; C23C 16/455; H01L 21/67

(52) U.S. Cl. CPC H01L 21/306; C23C 16/4412; C23C 16/45557; H01L 21/67017

(57) ABSTRACT

A substrate processing apparatus includes a plurality of processing units, an exhaust route, a gas processing device, and a controller. The exhaust route is provided where a gas that is discharged from the plurality of processing units. The gas processing device eliminates a target component in the gas and includes a duct, a partition plate, a liquid supply unit, and a concentration detection unit. The duct has a flow path. The partition plate partitions the flow path into a plurality of spaces and is formed of a porous material. The liquid supply unit supplies a dissolving liquid to the partition plate. The concentration detection unit detects a concentration of the target component. The controller regulates a flow volume of the dissolving liquid, based on at least one of operation information that indicates operation states of the plurality of processing units and a detection result of the concentration detection unit.

### FIELD

The present disclosure relates to a substrate processing apparatus and a control method for a substrate processing apparatus.

### BACKGROUND

A discharged gas that is discharged from a substrate processing apparatus that processes a substrate such as a semiconductor wafer may include a component of a chemical product that is used for processing of such a substrate, for example, an acid component and/or an alkali component, and/or an organic component.

A discharged gas that includes a component of a chemical product may be released to an atmospheric air so as to affect an environment and/or a human body. Hence, an elimination device that eliminates a chemical product component from a discharged gas and is called a scrubber may be installed on an exhaust route for a discharged gas in a substrate processing device.

Japanese Patent Application Publication No. 2010-114307 discloses a scrubber that has a housing that is provided with a nozzle that sprays a dissolving liquid that dissolves a chemical product component that is included in a discharged gas in an inside thereof and causes the dissolving liquid that is sprayed from the nozzle to contact the discharged gas that is introduced into the inside of the housing so as to eliminate the chemical product component from the discharged gas.

The present disclosure provides a technique that is capable of reducing an amount of a used dissolving liquid.

A substrate processing apparatus according to an aspect of the present disclosure includes a plurality of processing units, an exhaust route, a gas processing device, and a controller. The plurality of processing units process a substrate by using a chemical product. The exhaust route is provided where a gas that is discharged from the plurality of processing units passes and flows therethrough. The gas processing device is provided on the exhaust route and eliminates a target component that is included in the gas that passes and flows through the exhaust route from the gas. The controller controls the plurality of processing units and the gas processing device. The gas processing device includes a duct, a partition plate, a liquid supply unit, and a concentration detection unit. The duct has a flow path where the gas passes therethrough in an inside thereof. The partition plate partitions the flow path into a plurality of spaces where the partition plate is formed of a porous material that is capable of penetrating the gas and is capable of retaining a liquid. The liquid supply unit supplies a dissolving liquid that is capable of dissolving the target component that is included in the gas to the partition plate. The concentration detection unit detects a concentration of the target component that is included in the gas. The controller regulates a flow volume of the dissolving liquid that is supplied from the liquid supply unit to the partition plate, based on at least one of operation information that indicates operation states of the plurality of processing units and a detection result of the concentration detection unit.

### SUMMARY

According to an aspect of an embodiment, a substrate processing apparatus includes: a plurality of processing units that process a substrate by using a chemical product; an exhaust route where a gas that is discharged from the plurality of processing units passes and flows therethrough; a gas processing device that is provided on the exhaust route and eliminates a target component that is included in the gas that passes and flows through the exhaust route from the gas; and a controller that controls the plurality of processing units and the gas processing device, wherein the gas processing device includes: a duct that has a flow path where the gas passes therethrough in an inside thereof; a partition plate that partitions the flow path into a plurality of spaces where the partition plate is formed of a porous material that is capable of penetrating the gas and is capable of retaining a liquid; a liquid supply unit that supplies a dissolving liquid that is capable of dissolving the target component that is included in the gas to the partition plate; and a concentration detection unit that detects a concentration of the target component that is included in the gas, and the controller regulates a flow volume of the dissolving liquid that is supplied from the liquid supply unit to the partition plate, based on at least one of operation information that indicates operation states of the plurality of processing units and a detection result of the concentration detection unit.

### BRIEF DESCRIPTION OF DRAWINGS

FIG. 1 is a diagram that illustrates a general configuration of a substrate processing system according to a first embodiment;

FIG. 2 is a diagram that illustrates a configuration of a processing unit according to a first embodiment;

FIG. 3 is a diagram that illustrates a configuration of an exhaust route of a processing unit according to a first embodiment;

FIG. 4 is a diagram that illustrates a configuration of a gas processing device according to a first embodiment;

FIG. 5 is a flowchart that illustrates an example of a procedure of a flow volume regulation process according to a first embodiment;

FIG. 6 is a flowchart that illustrates an example of a procedure of an exhaust gas flow volume changing process according to a first embodiment;

FIG. 7 is a diagram that illustrates a configuration of a gas processing device according to a second embodiment;

FIG. 8 is a flowchart that illustrates an example of a procedure of an outside air flow volume changing process according to a second embodiment; and

FIG. 9 is a diagram that illustrates a configuration of a gas processing device according to a variation of a first embodiment.

### DESCRIPTION OF EMBODIMENTS

Hereinafter, an embodiment(s) of a substrate processing apparatus and a control method for a substrate processing apparatus as disclosed in the present application will be explained in detail, with reference to the accompanying drawing(s). Additionally, a disclosed technique(s) is/are not limited by an embodiment(s) as illustrated below.

### First Embodiment

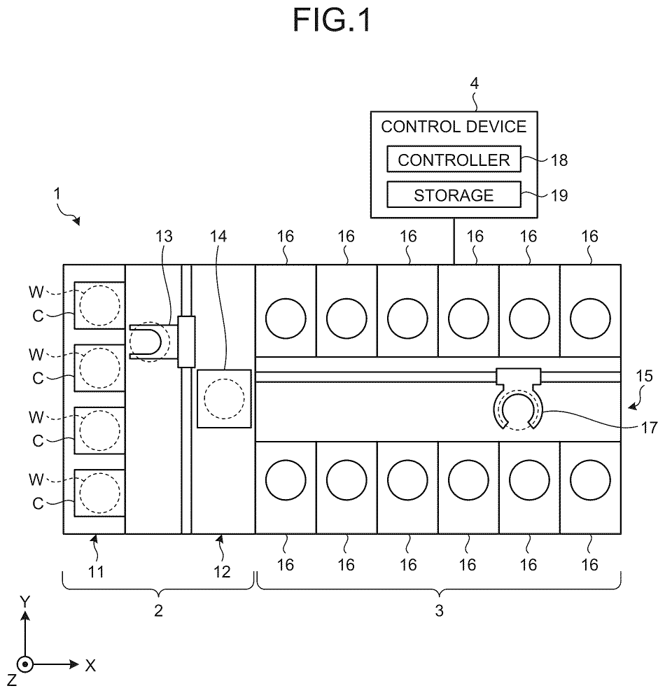

First, a configuration of a substrate processing system according to a first embodiment will be explained with reference to FIG. 1.

FIG. 1 is a diagram that illustrates a general configuration of a substrate processing system according to a first embodiment. Hereinafter, in order to clarify a positional relationship, an X-axis, a Y-axis, and a Z-axis that are orthogonal to one another are defined where a positive direction of such a Z-axis is provided as a vertically upward direction.

As illustrated in FIG. 1, a substrate processing system 1 includes a carry-in/out station 2 and a processing station 3. The carry-in/out station 2 and the processing station 3 are provided so as to be adjacent to one another.

The carry-in/out station 2 includes a carrier placing section 11 and a transfer section 12. In the carrier placing section 11, a plurality of carriers C that house a plurality of substrates, in the present embodiment, semiconductor wafers (wafers W, below) in horizontal states thereof are placed.

The transfer section 12 is provided so as to be adjacent to the carrier placing section 11 and includes a substrate transfer device 13 and a delivery unit 14 in an inside thereof. The substrate transfer device 13 includes a wafer holding mechanism that holds a wafer W. Furthermore, the substrate transfer device 13 is capable of moving in a horizontal direction and a vertical direction and turning around a vertical axis as a center, and executes transfer of a wafer W between a carrier C and the delivery unit 14 by using a wafer holding mechanism.

The processing station 3 is provided so as to be adjacent to the transfer section 12. The processing station 3 includes a transfer section 15 and a plurality of processing units 16. The plurality of processing units 16 are provided side by side on both sides of the transfer section 15.

The transfer section 15 includes a substrate transfer device 17 in an inside thereof. The substrate transfer device 17 includes a wafer holding mechanism that holds a wafer W. Furthermore, the substrate transfer device 17 is capable of moving in a horizontal direction and a vertical direction and turning around a vertical direction as a center, and executes transfer of a wafer W between the delivery unit 14 and a processing unit 16 by using a wafer holding mechanism.

A processing unit 16 executes predetermined substrate processing for a wafer W that is transferred by the substrate transfer device 17.

Furthermore, the substrate processing system 1 includes a control device 4. The control device 4 is, for example, a computer, and includes a controller 18 and a storage 19. The storage 19 stores a program that controls various types of processes that are executed in the substrate processing system 1. The controller 18 reads and executes a program that is stored in the storage 19 so as to control an operation of the substrate processing system 1.

Additionally, such a program may be recorded in a computer-readable storage medium and be installed in the storage 19 of the control device 4 from such a storage medium. For a computer-readable storage medium, for example, a hard disk (HD), a flexible disk (FD), a compact disk (CD), a magnetooptical disk (MO), a memory card, etc., are provided.

In the substrate processing system 1 configured as described above, first, the substrate transfer device 13 of the carry-in/out station 2 takes a wafer W from a carrier C that is placed in the carrier placing section 11 and places such a taken wafer W on the delivery unit 14. A wafer W that is placed on the delivery unit 14 is taken from the delivery unit 14 by the substrate transfer device 17 of the processing station 3 and is carried in a processing unit 16.

A wafer W that is carried in a processing unit 16 is processed by the processing unit 16, subsequently is carried out of the processing unit 16 by the substrate transfer device 17, and is placed on the delivery unit 14. Then, a processed wafer W that is placed on the delivery unit 14 is returned to a carrier C of the carrier placing section 11 by the substrate transfer device 13.

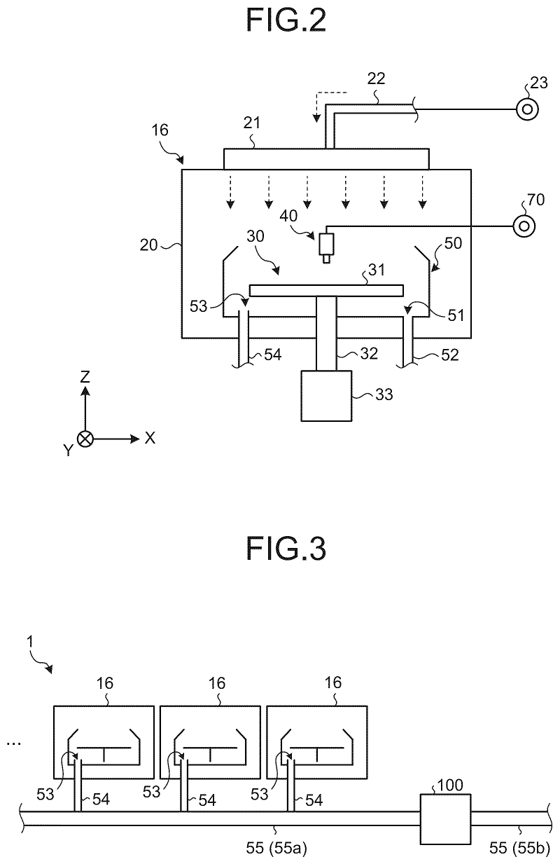

Next, a configuration of a processing unit 16 and an exhaust route of such a processing unit 16 will be explained with reference to FIG. 2 and FIG. 3. FIG. 2 is a diagram that illustrates a configuration of a processing unit 16 according to a first embodiment.

As illustrated in FIG. 2, a processing unit 16 includes a chamber 20, a substrate holding mechanism 30, a processing fluid supply unit 40, and a recovery cup 50.

The chamber 20 houses the substrate holding mechanism 30, the processing fluid supply unit 40, and the recovery cup 50. A ceiling part of the chamber 20 is provided with an FFU (Fan Filter Unit) 21. The FFU 21 is connected to a gas supply source 23 through a gas supply pipe 22. The FFU 21 supplies a gas that is supplied from the gas supply source 23 through the gas supply pipe 22 from an upper side toward a lower side in the chamber 20 so as to form a downflow in the chamber 20.

The substrate holding mechanism 30 includes a holding part 31, a supporting part 32, and a driving part 33. The holding part 31 holds a wager W horizontally. The supporting part 32 is a member that extends in a vertical direction where a proximal end part thereof is supported so as to be rotatable by the driving part 33 and a distal end part thereof supports the holding part 31 horizontally. The driving part 33 rotates the supporting part 32 around a vertical axis. Such a substrate holding mechanism 30 rotates the supporting part 32 by using the driving part 33 so as to rotate the holding part 31 that is supported by the supporting part 32 and thereby rotate a wafer W that is held by the holding part 31.

The processing fluid supply unit 40 supplies a processing fluid to a wafer W. The processing fluid supply unit 40 is connected to a processing fluid supply source 70.

The recovery cup 50 is arranged so as to surround the holding part 31 and traps a processing liquid that is scattered from a wafer W by rotation of the holding part 31. A drain port 51 is formed on a bottom part of the recovery cup 50. The drain port 51 is connected to a drain pipe 52 where a processing liquid that is trapped by the recovery cup 50 is discharged from the drain port 51 to an outside of a processing unit 16 through the drain pipe 52.

Furthermore, an exhaust port 53 that discharges a gas that is supplied from the FFU 21 to an outside of a processing unit 16 is formed on a bottom part of the recovery cup 50. The exhaust port 53 is connected to an exhaust pipe 54 where a gas that is supplied from the FFU 21 to a processing unit 16 is discharged from the exhaust port 53 to an outside of the processing unit 16 through the exhaust pipe 54.

Herein, a gas that is discharged from a processing unit 16 (that will be described as a “discharged gas” below) may include a component of a processing fluid that is supplied from the processing fluid supply unit 40. For example, in a case where a processing fluid is an acidic, alkaline, or organic chemical product, an acid component, an alkali component, or an organic component may be included in a discharged gas, respectively.

Additionally, for an acidic chemical product, for example, DHF (dilute hydrofluoric acid), BHF (a mixed liquid of hydrofluoric acid and ammonium fluoride), etc., are provided. Furthermore, an alkaline chemical product, for example, SC1 (a mixed liquid of ammonia, a hydrogen peroxide solution, and water) is provided. Furthermore, for an organic chemical product, for example, IPA (isopropyl alcohol) is provided. A chemical product is not limited to a liquid and may be a gas.

A discharged gas that includes a component as described above may be released to an atmospheric air so as to affect an environment and/or a human body. Hence, the substrate processing system 1 according to a first embodiment includes a gas processing device 100 (see FIG. 3) that eliminates a target component that includes at least one of an acid component, an alkali component, and an organic component from a discharged gas that is discharged from a processing unit 16. The gas processing device 100 is provided on an exhaust path that is included in the substrate processing system 1.

FIG. 3 is a diagram that illustrates a configuration of an exhaust route of a processing unit 16 according to a first embodiment. As illustrated in FIG. 3, a substrate processing system 1 according to a first embodiment includes a plurality of exhaust pipes 54. One-ends of the plurality of exhaust pipes 54 are connected to exhaust ports 53 of a plurality of processing units 16 and another-ends thereof are connected to a collective exhaust pipe 55.

As illustrated in FIG. 3, the gas processing device 100 is provided on the collective exhaust pipe 55. The collective exhaust pipe 55 composes a part of an exhaust route that is included in the substrate processing system 1 and is provided inside the substrate processing system 1. Then, the gas processing device 100 is also provided inside the substrate processing system 1. A discharged gas where a target component is eliminated therefrom by the gas processing device 100 is discharged from the substrate processing system 1 through the collective exhaust pipe 55. Additionally, in a case where the collective exhaust pipe 55 extends to an outside of the substrate processing system 1, the gas processing device 100 may be provided outside the substrate processing system 1. Furthermore, in a case where a plurality of collective exhaust pipes 55 that are respectively provided on a plurality of substrate processing systems 1 are connected to one confluent exhaust pipe, the gas processing device 100 may be provided on such a confluent exhaust pipe.

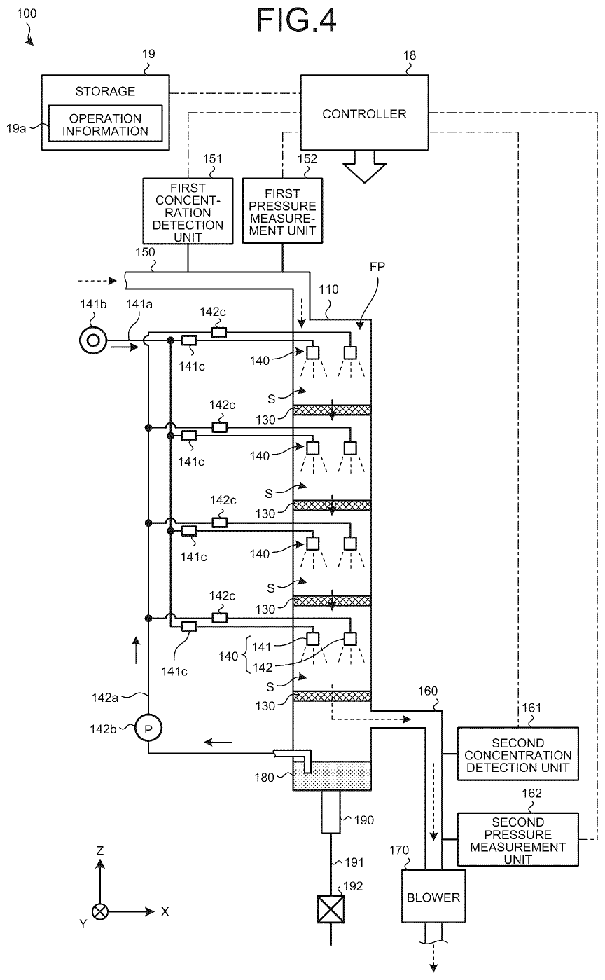

Next, a configuration of a gas processing device 100 will be explained with reference to FIG. 4. FIG. 4 is a diagram that illustrates a configuration of a gas processing device 100 according to a first embodiment. Additionally, in FIG. 4, a flow of a discharged gas is represented by a dashed arrow and a flow of a dissolving liquid is represented by a solid arrow.

As illustrated in FIG. 4, the gas processing device 100 includes a duct 110, a partition plate 130, a liquid supply unit 140, a gas introduction unit 150, a gas discharge unit 160, a blower 170, a storage tank 180, and a liquid discharge unit 190.

The duct 110 has a flow path FP in an inside thereof. The duct 110 is arranged so as to extend in upward and downward directions (directions of a Z-axis). A shape of the duct 110 may be, for example, any shape such as a circularly cylindrical shape and/or a square pipe shape.

The gas introduction unit 150 connects an upstream side collective exhaust pipe 55a (see FIG. 3) that is positioned at an upstream side of the gas processing device 100 among a collective exhaust pipes 55 and the duct 110, and introduces a discharged gas that flows through the upstream side collective exhaust pipe 55a into a flow path FP. Furthermore, the gas discharge unit 160 connects a downstream side collective exhaust pipe 55b (see FIG. 3) that is positioned at a downstream side of the gas processing device 100 among the collective exhaust pipes 55 and the duct 110, discharges a discharged gas that passes through a flow path FP from the duct 110, and sends it to the downstream side collective exhaust pipe 55b.

Specifically, the gas introduction unit 150 is connected to an upper end side of the duct 110, and introduces a discharged gas from such an upper end side of the duct 110 (that is, a top part of a flow path FP) into a flow path FP. Furthermore, the gas discharge unit 160 is connected to a lower end side of the duct 110, and discharges a discharged gas from such a lower end side of the duct 110 (that is, a bottom part of a flow path FP) to the downstream side collective exhaust pipe 55b. Therefore, a flow of a discharged gas from an upper side toward a lower side is formed on a flow path FP.

The gas discharge unit 160 is provided with the blower 170. The blower 170 has a fan in an inside thereof where such a fan is rotated so as to change a flow volume of a discharged gas. The blower 170 is an example of a changing unit.

The partition plate 130 is arranged on a flow path FP of the duct 110. The partition plate 130 partitions a flow path FP into a plurality of spaces S that are adjacent to one another in upward and downward directions.

The partition plate 130 is a porous member that is formed of a porous material that is capable of penetrating a discharged gas and is capable of retaining a liquid. For a porous material that forms the partition plate 130, for example, a porous ceramic(s) is/are used. A porous ceramic(s) is/are a ceramic(s) that include(s) at least silicon (Si) and silicon carbide (SiC). A porous ceramic(s) is/are formed in such a manner that a three-dimensional skeleton that is composed of silicon (Si) is reinforced with silicon carbide (SiC). A porous ceramic(s) may further include aluminum nitride and/or silicon nitride.

The partition plate 130 is attached to a plurality of attachment positions that are capable of adjusting sizes of a plurality of spaces S of a flow path FP so as to be attachable and detachable. For example, on a flow path FP, a plurality of rails that extend in horizontal directions are formed at an regular interval(s) in upward and downward directions, and the partition plate 130 is attached to a desired rail among a plurality of rails of such a flow path FP so as to be attachable and detachable. The partition plate 130 is attached to all rails of a flow path FP, so that sizes of a plurality of spaces S are identical to one another. The partition plate 130 is detached from some rails among all rails, so that it is possible to increase sizes of some spaces S. Sizes of a plurality of spaces S may be identical to or different from one another in the duct 110.

At least one liquid supply unit 140 is arranged in each space S. Specifically, the liquid supply unit 140 is arranged above the partition plate 130 in each space S. The liquid supply unit 140 supplies a dissolving liquid toward the partition plate 130 on a lower side thereof.

The liquid supply unit 140 has a first liquid supply unit 141 and a second liquid supply unit 142.

The first liquid supply unit 141 is connected to a dissolving liquid supply source 141b through a supply pipe 141a. The supply pipe 141a is provided with a supply instrument group 141c that corresponds to the first liquid supply unit 141 in each space S. The dissolving liquid supply source 141b supplies, for example, a pure water and/or a city water as a dissolving liquid that dissolves a target component that is included in a discharged gas. Additionally, a dissolving liquid that is supplied from the dissolving liquid supply source 141b is not limited to a pure water and/or a city water and is appropriately selectable depending on a type of a target component that is included in a discharged gas. The supply instrument group 141c includes, for example, an on-off valve that opens or closes the supply pipe 141a, a mass flow controller, and a temperature regulator that is capable of regulating a temperature of a dissolving liquid, etc.

The first liquid supply unit 141 supplies a dissolving liquid that is supplied from the dissolving liquid supply source 141b to the partition plate 130 on a lower side thereof. A dissolving liquid that is supplied to the partition plate 130 permeates a porous structure inside the partition plate 130 from a top surface of the partition plate 130 so as to be temporarily retained by the partition plate 130.

The second liquid supply unit 142 is connected to a circulating liquid pipe 142a. The circulating liquid pipe 142a is provided with a pump 142b. Furthermore, the circulating liquid pipe 142a is provided with a supply instrument group 142c that corresponds to the second liquid supply unit 142 in each space S. The circulating liquid pipe 142a contacts a used dissolving liquid that is stored in the storage tank 180, that is, a dissolving liquid that includes a target component that is eliminated from a discharged gas. The pump 142b suctions a dissolving liquid from the storage tank 180 through the circulating liquid pipe 142a so as to pressurize and send it toward the second liquid supply unit 142. Thereby, a dissolving liquid that is stored in the storage tank 180 is circulated through a circulation route that is composed of the circulating liquid pipe 142a and the pump 142b. The supply instrument group 141c includes, for example, an on-off valve that opens or closes the circulating liquid pipe 142a, a mass flow controller, and a temperature regulator that is capable of regulating a temperature of a circulating liquid, etc.

The second liquid supply unit 142 supplies a circulating liquid that is obtained by circulating a dissolving liquid that is stored in the storage tank 180 through a circulation route to the partition plate 130 on a lower side thereof. A circulating liquid that is supplied to the partition plate 130 permeates a porous structure inside the partition plate 130 from a top surface of the partition plate 130 so as to be temporarily retained by the partition plate 130. Hereinafter, a circulating liquid that is supplied from the second liquid supply unit 142 and a dissolving liquid that is supplied from the first liquid supply unit 141 may collectively be called a “dissolving liquid” appropriately.

The liquid supply unit 140 supplies a dissolving liquid from an upstream side of a flow path FP toward the partition plate 130 on a lower side thereof inside the duct 110.

The storage tank 180 stores a dissolving liquid that falls from the partition plate 130.

The liquid discharge unit 190 discharges a dissolving liquid that is stored in the storage tank 180 from the storage tank 180. The liquid discharge unit 190 is connected to a drain pipe 191 and the drain pipe 191 is provided with a valve 192. Furthermore, the storage tank 180 is provided with a liquid level detection unit that detects a liquid level of a dissolving liquid in the storage tank 180, and in a case where a liquid level is detected by such a liquid level detection unit, the valve 192 is opened. Thereby, a used dissolving liquid that is stored in the storage tank 180 is discharged to an outside thereof through the drain pipe 191.

The gas processing device 100 is configured as described above where a discharges gas that is introduced from the gas introduction unit 150 into a flow path FP of the duct 110 penetrates the partition plate 130 and passes through such a flow path FP from an upper side toward a lower side.

The partition plate 130 retains a dissolving liquid. Therefore, a discharged gas contacts a dissolving liquid that is retained by the partition plate 130 while penetrating the partition plate 130 and passing through a flow path FP from an upper side toward a lower side.

A discharged gas contacts a dissolving liquid that is retained by the partition plate 130, so that a target component that is included in such a discharged gas is dissolved in such a dissolving liquid. Thereby, a target component is eliminated from a discharged gas. A discharged gas where a target component is eliminated therefrom is discharged from a flow path FP of the duct 110 to a downstream side collective exhaust pipe 55b (see FIG. 3) by the gas discharge unit 160. Furthermore, a dissolving liquid that includes a target component that is eliminated from a discharged gas falls from the partition plate 130 and is stored in the storage tank 180, and subsequently, is discharged from the storage tank 180 by the liquid discharge unit 190.

Thus, the gas processing device 100 retains a dissolving liquid by the partition plate 130 that is formed of a porous material that is capable of penetrating a discharged gas and is capable of retaining a liquid, and causes a discharged gas to contact such a dissolving liquid that is retained by the partition plate 130 so as to eliminate a target component from such a discharged gas.

A dissolving liquid that is retained by the partition plate 130 tends to stay at such a place temporarily, so that it is possible to stay such a dissolving liquid in the duct 110 for a longer period of time, as compared with a scrubber that sprays a dissolving liquid constantly. Therefore, it is possible for the gas processing device 100 to reduce an amount of a used dissolving liquid as compared with a scrubber.

Furthermore, the gas processing device 100 includes a first concentration detection unit 151 and a second concentration detection unit 161. The first concentration detection unit 151 is provided on the gas introduction unit 150 and detects a concentration of a target component that is included in a discharged gas that is introduced into a flow path FP of the duct 110 by the gas introduction unit 150. Furthermore, the second concentration detection unit 161 is provided on the gas discharge unit 160 and detects a concentration of a target component that is included in a discharged gas that is discharged from a flow path FP of the duct 110 by the gas discharge unit 160.

A result of detection that is executed by the first concentration detection unit 151 and the second concentration detection unit 161 is output to the controller 18. Furthermore, the supply instrument groups 141c, 142c, and the pump 142b are controlled by the controller 18.

Meanwhile, in the substrate processing system 1, operation states of a plurality of processing units 16 vary moment by moment. Hence, a period of time when one processing unit 16 is operated (that executes substrate processing that uses a processing fluid) and a period of time when none of processing units 16 is operated are provided. Hereinafter, a period of time when one processing unit 16 is operated will be called an “operation time period” and a period of time when none of processing units 16 is operated will be called a “non-operation time period”. Furthermore, in the substrate processing system 1, a concentration of a target component that is included in a discharged gas is changed depending on operation states of a plurality of processing units 16.

If a flow volume of a dissolving liquid that is supplied from the liquid supply unit 140 to the partition plate 130 is constant within an operation time period or a non-operation time period regardless of a concentration of a target component that is included in such a discharged gas, such a dissolving liquid may needlessly be consumed. For example, in a case where a concentration of a target component that is included in a discharged gas is not so high within an operation time period or a non-operation time period, it is considered that such a target component is sufficiently eliminated from such a discharged gas even if a flow volume of a dissolving liquid is decreased.

Hence, the controller 18 executes a flow volume regulation process that regulates a flow volume of a dissolving liquid that is supplied from the liquid supply unit 140 to the partition plate 130, based on operation information that indicates operation states of a plurality of processing units 16 and a detection result of the first concentration detection unit 151 (or the second concentration detection unit 161).

For such a flow volume regulation process, for example, operation information 19a that is stored in the storage 19 is used. The operation information 19a is information that includes an operation time period when one processing unit 16 is operated and a non-operation time period when none of processing units 16 is operated.

The controller 18 executes a flow volume regulation process, based on the operation information 19a and a detection result of the first concentration detection unit 151 (or the second concentration detection unit 161). That is, the controller 18 regulates a flow volume of a dissolving liquid that is supplied from the first liquid supply unit 141 to the partition plate 130 and a flow volume of a circulating liquid that is supplied from the second liquid supply unit 142 to the partition plate 130, based on the operation information 19a and a detection result of the first concentration detection unit 151 (or the second concentration detection unit 161).

As such a flow volume regulation process is executed, it is possible to decrease a flow volume of a dissolving liquid that is supplied to the partition plate 130 in a case where a concentration of a target component that is included in a discharged gas is not so high within an operation time period or a non-operation time period. Thus, it is possible to reduce or prevent excessive use of a dissolving liquid, so that it is possible to reduce an amount of a used dissolving liquid. A content of a flow volume regulation process for a dissolving liquid that is executed by the controller 18 will be described later.

Furthermore, the gas processing device 100 includes a first pressure measurement unit 152 and a second pressure measurement unit 162. The first pressure measurement unit 152 is provided on the gas introduction unit 150 and measures a pressure of a discharged gas that is introduced into a flow path FP of the duct 110 by the gas introduction unit 150. Furthermore, the second pressure measurement unit 162 is provided on the gas discharge unit 160 and measures a pressure of a discharged gas that is discharged from a flow path FP of the duct 110 by the gas discharge unit 160.

A result of measurement that is executed by the first pressure measurement unit 152 and the second pressure measurement unit 162 is output to the controller 18. Furthermore, the blower 170 is controlled by the controller 18.

Herein, if a rotational speed of a fan in the blower 170 is constant regardless of a pressure of a discharged gas, a flow volume of a discharged gas that is introduced into a flow path FP of the duct 110 by the gas introduction unit 150 is decreased due to a pressure loss of the partition plate 130 that retains a dissolving liquid. Accordingly, a flow volume of a discharged gas that is discharged from a processing unit 16 is deceased so as to lose a balance between gas supply and gas discharge in such a processing unit 16, so that a pressure in such a processing unit 16 may vary.

On the other hand, the controller 18 executes an exhaust gas flow volume changing process that adjusts a rotational speed of a fan in the blower 170 based on a measurement result of the first pressure measurement unit 152 (or the second pressure measurement unit 162), so as to change a flow volume of a discharged gas that is introduced into a flow path FP of the duct 110. Thereby, it is possible to reduce or prevent a decrease in a flow volume of a discharged gas that is caused by a pressure loss of the partition plate 130 that retains a dissolving liquid, so that it is possible to reduce or prevent a pressure variation in a processing unit 16 that is associated with a decrease in a flow volume of an exhaust gas. A content of an exhaust gas flow volume changing process that is executed by the controller 18 will be described later.

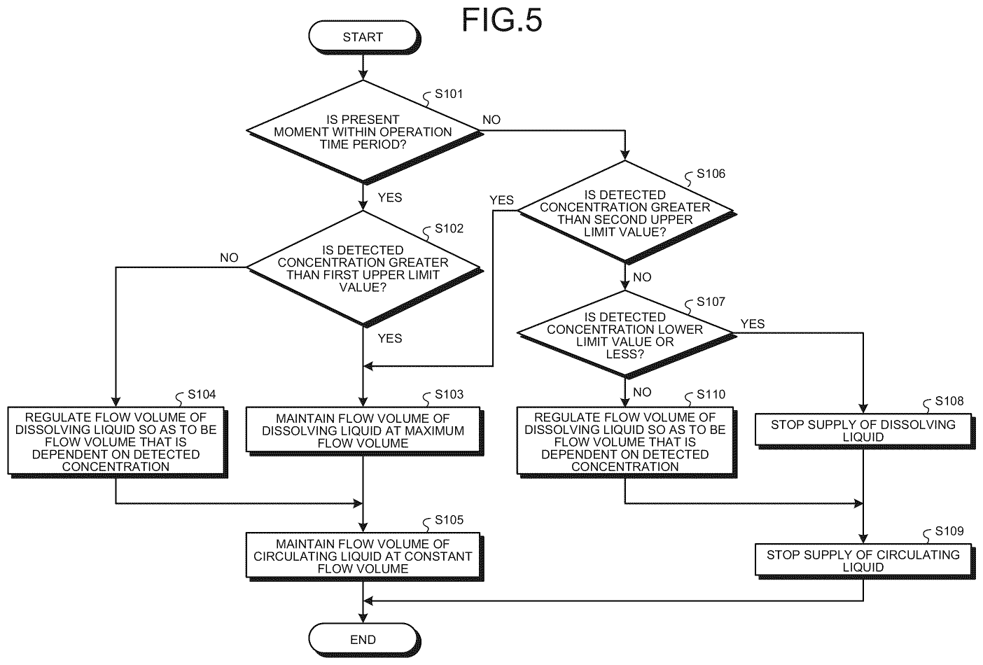

Next, a flow volume regulation process for a dissolving liquid that is executed by a controller 18 will be explained with reference to FIG. 5. FIG. 5 is a flowchart that illustrates an example of a procedure of a flow volume regulation process according to a first embodiment. A flow volume regulation process as illustrated in FIG. 5 is executed, for example, with a predetermined period.

As illustrated in FIG. 5, a controller 18 determines whether or not a present moment is within an operation time period, with reference to operation information 19a that is stored in a storage 19 (step S101). In a case where it is determined that a present moment is within an operation time period (step S101; Yes), the controller 18 executes a following process. That is, the controller 18 determines whether or not a concentration that is detected by a second concentration detection unit 161, that is, a concentration of a target component that is included in a discharged gas that flows through a gas discharge unit 160 is greater than a predetermined first upper limit value (step S102). A first upper limit value is, for example, 400 ppm.

In a case where a concentration that is detected by the second concentration detection unit 161 is greater than a first upper limit value (step S102; Yes), the controller 18 controls a supply instrument group 141c in such a manner that a flow volume of a dissolving liquid that is supplied from a first liquid supply unit 141 to a partition plate 130 is maintained at a predetermined maximum flow volume (step S103).

As a flow volume of a dissolving liquid that is supplied from the first liquid supply unit 141 to the partition plate 130 is increased, such a dissolving liquid is used excessively. In such a case, a flow volume of a dissolving liquid is maintained at a predetermined maximum flow volume, so that it is possible to reduce or prevent excessive use of such a dissolving liquid.

On the other hand, in a case where a concentration that is detected by the second concentration detection unit 161 is a first upper limit value or less (step S102; No), the controller 18 controls the supply instrument group 141c in such a manner that a flow volume of a dissolving liquid that is supplied from the first liquid supply unit 141 to the partition plate 130 is regulated so as to be a flow volume that is dependent on a detected concentration (step S104). For example, as a concentration that is detected by the second concentration detection unit 161 is decreased, the controller 18 decreases a flow volume of a dissolving liquid that is supplied from the first liquid supply unit 141 to the partition plate 130.

In a case where a concentration that is detected by the second concentration detection unit 161 is a first upper limit value or less, a target component may needlessly be eliminated from a discharged gas. In such a case, a flow volume of a dissolving liquid may be decreased so as to decrease efficiency of dissolving of a target component in a dissolving liquid. Thus, it is possible to reduce or prevent excessive use of a dissolving liquid.

Furthermore, the controller 18 controls a supply instrument group 142c in such a manner that a flow volume of a circulating liquid that is supplied from a second liquid supply unit 142 to the partition plate 130 is maintained at a constant flow volume, regardless of a concentration that is detected by the second concentration detection unit 161 (step S105).

Thus, a flow volume of a circulating liquid is maintained at a constant flow volume, regardless of a concentration that is detected by the second concentration detection unit 161, so that a used dissolving liquid where a target component is adsorbed therein is quickly replaced with a flesh dissolving liquid. Thereby, efficiency of dissolving of a target component in a dissolving liquid is increased, so that it is possible to decrease a concentration of such a target component that is included in a discharged gas that is discharged from the gas discharge unit 160.

On the other hand, in a case where it is determined at step S101 that a present moment is not within an operation time period, in other words, it is determined that such a present moment is within a non-operation time period (step S101; No), the controller 18 executes a following process. That is, the controller 18 determines whether or not a concentration that is detected by the second concentration detection unit 161, that is, a concentration of a target component that is included in a discharged gas that flows through the gas discharge unit 160 is greater than a predetermined second upper limit value (step S106). A second upper limit value is, for example, 600 ppm.

In a case where a concentration that is detected by the second concentration detection unit 161 is greater than a second upper limit value (step S106; Yes), the controller 18 moves a process to step S103 and executes processes at steps S103, S105. That is, the controller 18 controls the supply instrument group 141c in such a manner that a flow volume of a dissolving liquid that is supplied from the first liquid supply unit 141 to the partition plate 130 is maintained at a predetermined maximum flow volume. Then, the controller 18 controls the supply instrument group 142c in such a manner that a flow volume of a circulating liquid that is supplied from the second liquid supply unit 142 to the partition plate 130 is maintained at a constant flow volume.

In a case where a concentration that is detected by the second concentration detection unit 161 within a non-operation time period is greater than a second upper limit value, a target component stays in a processing unit 16 and/or in a collective exhaust pipe 55 and a discharged gas that includes a staying target component is introduced into a flow path FP of the duct 110. In such a case, a flow volume of a dissolving liquid is maintained at a predetermined maximum flow volume and a flow volume of a circulating liquid is maintained at a constant flow volume, so that it is possible to decrease a concentration of a target component that is included in a discharged gas that is discharged from the gas discharge unit 160.

On the other hand, in a case where a concentration that is detected by the second concentration detection unit 161 is a second upper limit value or less (step S106; No), the controller 18 determines whether or not a concentration that is detected by the second concentration detection unit 161 is a predetermined lower limit value or less (step S107). A lower limit value is, for example, 200 ppm.

In a case where a concentration that is detected by the second concentration detection unit 161 is a predetermined lower limit value or less (step S107; Yes), the controller 18 executes a following process. That is, the controller 18 controls the supply instrument group 141c so as to stop supply of a dissolving liquid from the first liquid supply unit 141 to the partition plate 130 (step S108). Then, the controller 18 controls the supply instrument group 142c and a pump 142b so as to stop supply of a circulating liquid from the second liquid supply unit 142 to the partition plate 130 (step S109).

In a case where a concentration that is detected by the second concentration detection unit 161 is a predetermined lower limit value or less, a target component is needlessly eliminated from a discharged gas. In such a case, supply of a dissolving liquid and supply of a circulating liquid may be stopped. Thus, it is possible to reduce or prevent excessive use of a cleaning liquid.

On the other hand, in a case where a concentration that is detected by the second concentration detection unit 161 is greater than a lower limit value (step S107; No), the controller 18 controls the supply instrument group 141c in such a manner that a flow volume of a dissolving liquid that is supplied from the first liquid supply unit 141 to the partition plate 130 is regulated so as to be a flow volume that is dependent on a detected concentration (step S110). Then, the controller 18 moves a process to step S109.

In a case where a concentration that is detected by the second concentration detection unit 161 within a non-operation time period is greater than a lower limit value, a target component stays in a processing unit 16 and/or in the collective exhaust pipe 55 and a discharged gas that includes a staying target component is introduced into a flow path FP of the duct 110. In such a case, a flow volume of a dissolving liquid is maintained at a flow volume that is dependent on a detected concentration, so that it is possible to decrease a concentration of a target component that is included in a discharged gas that is discharged from the gas discharge unit 160.

In a case where processes at steps S105, S109 are ended, the controller 18 ends a flow volume regulation process.

Additionally, although flow volume regulation is executed based on the operation information 19a and a detection result of the second concentration detection unit 161 herein, the controller 18 may execute a flow volume regulation process at steps S101 to S110 based on the operation information 19a and a detection result of a first concentration detection unit 151. Furthermore, a flow volume regulation process at steps S101 to S110 that is executed by the controller 18 may be executed by using a concentration that is detected by a (non-illustrated) third concentration detection unit that detects a concentration of a target component that is included in a discharged gas that passes through a flow path FP of the duct 110.

Furthermore, the controller 18 may execute a flow volume regulation process based on the operation information 19a. For example, the controller 18 may regulate flow volumes of a dissolving liquid and a circulating liquid so as to be predetermined flow volumes in a case where a present moment is within an operation time period with reference to the operation information 19a that is stored in the storage 19 or stop supply of a dissolving liquid and a circulating liquid in a case where such a present moment is within a non-operation time period.

Furthermore, the controller 18 may execute a flow volume regulation process based on a detection result of the second concentration detection unit 161. For example, the controller 18 may increase flow volumes of a dissolving liquid and a circulating liquid in a case where a concentration that is detected by the second concentration detection unit 161 is greater than a predetermined upper limit value, or decrease flow volumes of a dissolving liquid and a circulating liquid in a case where a concentration that is detected by the second concentration detection unit 161 is less than a predetermined lower limit value.

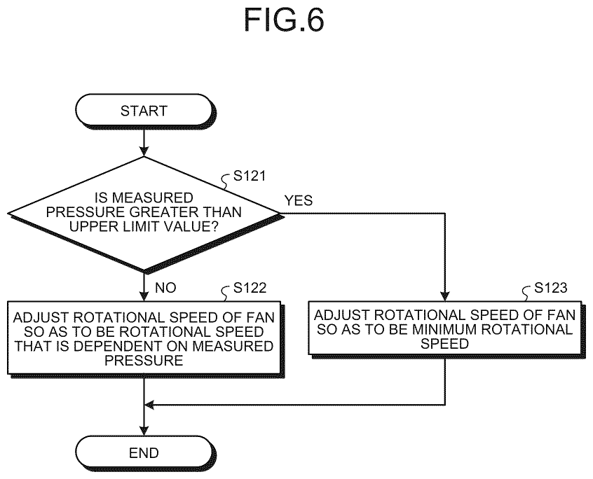

Next, an exhaust gas flow volume changing process that is executed by a controller 18 will be explained with reference to FIG. 6. FIG. 6 is a flowchart that illustrates an example of a procedure of an exhaust gas flow volume changing process according to a first embodiment. An exhaust gas flow volume changing process as illustrated in FIG. 6 is executed, for example, with a predetermined period.

As illustrated in FIG. 6, the controller 18 determines whether or not a pressure that is measured by a second pressure measurement unit 162, that is, a pressure of a discharged gas that flows through a gas discharge unit 160 is greater than a predetermined upper limit value (step S121). An upper limit value is, for example, 500 Pa.

In a case where a pressure that is measured by the second pressure measurement unit 162 is an upper limit value or less (step S121; No), the controller 18 adjusts a rotational speed of a fan in a blower 170 so as to be a rotational speed that is dependent on a measured pressure, so that a flow volume of a discharged gas that is introduced into a flow path FP of a duct 110 is changed (step S122). For example, as a pressure that is measured by the second pressure measurement unit 162 is decreased, the controller 18 increases a rotational speed of a fan in the blower 170 so as to increase a flow volume of a discharged gas that is introduced into a flow path FP pf the duct 110.

As a flow volume of a discharged gas that is introduced into a flow path FP of the duct 110 is increased, a flow volume of a discharged gas that is discharged from a processing unit 16 is increased, so as to stabilize a balance between gas supply and gas discharge in such a processing unit 16. Thereby, it is possible to reduce or prevent a pressure variation in a processing unit 16 that is associated with a decrease in a flow volume of an exhaust gas.

On the other hand, in a case where a pressure that is measured by the second pressure measurement unit 162 is greater than an upper limit value (step S121; Yes), the controller 18 adjusts a rotational speed of a fan in the blower 170 so as to be a predetermined minimum rotational speed (step S123). For example, the controller 18 adjusts a rotational speed of a fan in the blower 170 so as to be 0 that is a minimum rotational speed, so that the blower 170 is stopped.

In a case where a pressure that is measured by the second pressure measurement unit 162 is greater than an upper limit value, a discharged gas is needlessly introduced into a flow path FP of the duct 110. In such a case, a rotational speed of a fan in the blower 170 may be adjusted so as to be a predetermined minimum rotational speed, so that a flow volume of a discharged gas that is introduced into a flow path FP of the duct 110 is decreased. Thus, it is possible to reduce or prevent a rapid increase in a pressure of an exhaust gas in a processing unit 16.

As described above, a substrate processing apparatus according to a first embodiment (for example, a substrate processing system 1) includes a plurality of processing units (for example, processing units 16), an exhaust route (for example, a collective exhaust pipe 55), a gas processing device (for example, a gas processing device 100), and a controller (for example, a controller 18). The plurality of processing units process a substrate (for example, a wafer W) by using a chemical product (for example, a processing fluid). The exhaust route is provided where a gas (for example, a discharged gas) that is discharged from the plurality of processing units passes and flows therethrough. The gas processing device is provided on the exhaust route and eliminates a target component that is included in the gas that passes and flows through the exhaust route from the gas. The controller controls the plurality of processing units and the gas processing device. The gas processing device includes a duct (for example, a duct 110), a partition plate (for example, a partition plate 130), a liquid supply unit (for example, a liquid supply unit 140), and a concentration detection unit (for example, a first concentration detection unit 151, a second concentration detection unit 161). The duct has a flow path (for example, a flow path FP) where the gas passes therethrough in an inside thereof. The partition plate partitions the flow path into a plurality of spaces where the partition plate is formed of a porous material that is capable of penetrating the gas and is capable of retaining a liquid. The liquid supply unit supplies a dissolving liquid that is capable of dissolving the target component that is included in the gas to the partition plate. The concentration detection unit detects a concentration of the target component that is included in the gas. The controller regulates a flow volume of the dissolving liquid that is supplied from the liquid supply unit to the partition plate, based on at least one of operation information (for example, operation information 19a) that indicates operation states of the plurality of processing units and a detection result of the concentration detection unit. Thereby, in a substrate processing apparatus according to a first embodiment, it is possible to reduce an amount of a used dissolving liquid.

### Second Embodiment

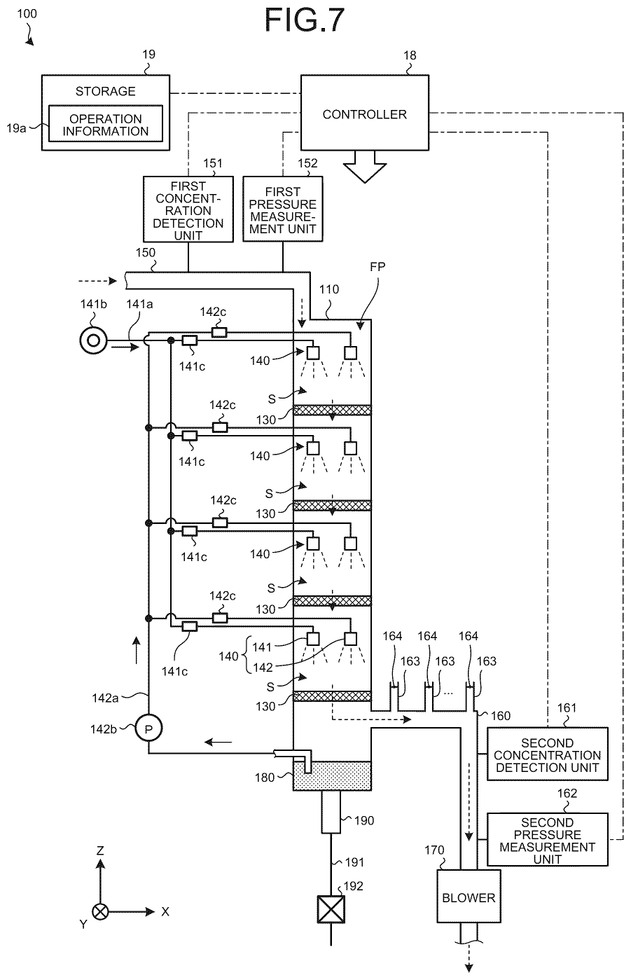

Next, a configuration of a gas processing device 100 according to a second embodiment will be explained with reference to FIG. 7. FIG. 7 is a diagram that illustrates a configuration of a gas processing device 100 according to a second embodiment. Additionally, in FIG. 7, a flow of a discharged gas is represented by a dashed arrow and a flow of a dissolving liquid is represented by a solid arrow, similarly to FIG. 4. Furthermore, in FIG. 7, a part that is identical to that in FIG. 4 will be provided with an identical sign.

A gas processing device 100 of a substrate processing system 1 according to a second embodiment further includes a plurality of outside air inlets 163 and a plurality of on-off valves 164, in addition to a configuration as illustrated in FIG. 4.

The plurality of outside air inlets 163 are provided on an upstream side of a blower 170 of a gas discharge unit 160 and is capable of incorporating outside air. The plurality of on-off valves 164 are respectively provided on the plurality of outside air inlets 163. Opening/closing of the plurality of on-off valves 164 is controlled by a controller 18.

The controller 18 executes a flow volume regulation process for a dissolving liquid while maintaining a rotational speed of a fan in the blower 170 at a constant level. Then, the controller 18 separately controls opening/closing of the plurality of on-off valves 164 depending on a flow volume of a dissolving liquid when executing a flow volume regulation process, so that an outside air flow volume changing process is executed that changes a flow volume of outside air that is incorporated from the plurality of outside air inlet 163 into the gas discharge unit 160.

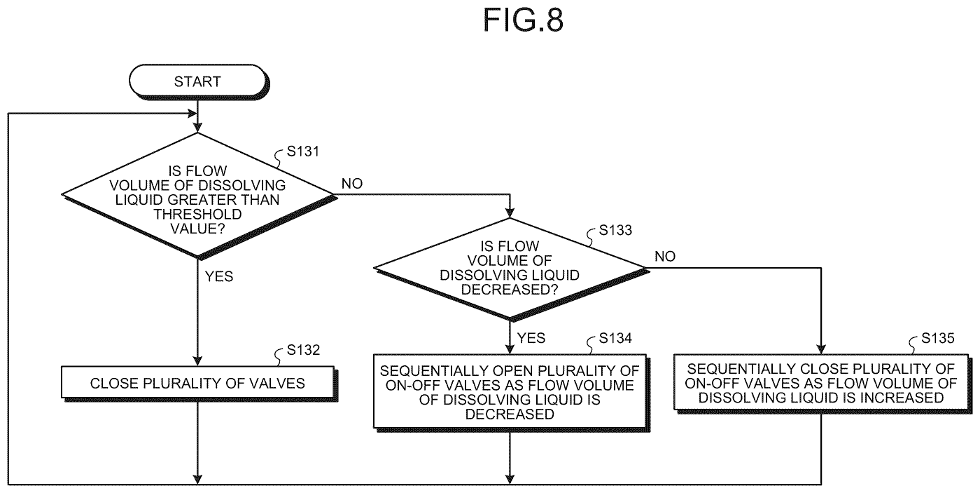

Next, an outside air flow volume changing process that is executed by a controller 18 will be explained with reference to FIG. 8. FIG. 8 is a flowchart that illustrates an example of a procedure of an outside air flow volume changing process according to a second embodiment. An outside air flow volume changing process as illustrated in FIG. 8 is executed during a flow volume regulation process for a dissolving liquid.

As illustrated in FIG. 8, the controller 18 determines whether or not a flow volume of a dissolving liquid that is supplied from a liquid supply unit 140 to a partition plate 13 is greater than a predetermined threshold value (step S131). In a case where a flow volume of a dissolving liquid that is supplied from the liquid supply unit 140 to the partition plate 130 is greater than a threshold value (step S131; Yes), the controller 18 closes all of a plurality of on-off valves 164 so as to stop incorporation of outside air from a plurality of outside air inlets 163 into a gas discharge unit 160 (step S132).

In a case where a flow volume of a dissolving liquid that is supplied from the liquid supply unit 140 to the partition plate 130 is greater than a threshold value, a pressure loss of the partition plate 130 that retains such a dissolving liquid is comparatively high and a flow volume of a discharged gas that is introduced into a flow path FP of a duct 110 by a gas introduction unit 150 is maintained within a proper range. In such a case, incorporation of outside air from the plurality of outside air inlets 163 into the gas discharge unit 160 may be stopped so as not to change a flow volume of a discharged gas that is introduced into a flow path FP of the duct 110. Thus, it is possible to reduce or prevent a pressure variation in a processing unit 16.

On the other hand, in a case where a flow volume of a dissolving liquid that is supplied from the liquid supply unit 140 to the partition plate 130 is a threshold value or less (step S131; No), the controller 18 determines whether or not a flow volume of such a dissolving liquid is decreased (step S133). In a case where a flow volume of a dissolving liquid is decreased (step S133; Yes), the controller 18 sequentially opens the plurality of on-off valves 164 as a flow volume of a dissolving liquid is decreased, so as to increase a flow volume of outside air that is incorporated from the plurality of outside air inlets 163 to the gas discharge unit 160 (step S134).

In a case where a flow volume of a dissolving liquid that is supplied from the liquid supply unit 140 to the partition plate 130 is decreased, a pressure loss of the partition plate 130 that retains a dissolving liquid may be decreased so as to rapidly increase a flow volume of a discharged gas that is introduced into a flow path FP of the duct 110 by the gas introduction unit 150. In such a case, a flow volume of outside air that is incorporated from the plurality of outside air inlets 163 into the gas discharge unit 160 is increased, so that it is possible to reduce or prevent an increase in a flow volume of a discharged gas that is introduced into a flow path FP of the duct 110 by the gas introduction unit 150. Thereby, it is possible to reduce or prevent a pressure variation in a processing unit 16 that is associated with an increase in a flow volume of an exhaust gas.

On the other hand, in a case where a flow volume of a dissolving liquid is increased (step S133; No), the controller 18 sequentially closes the plurality of on-off valves 164 as a flow volume of such a dissolving liquid is increased, so as to decrease a flow volume of outside air that is incorporated from the plurality of outside air inlets 163 into the gas discharge unit 160 (step S135).

In a case where a flow volume of dissolving liquid that is supplied from the liquid supply unit 140 to the partition plate 130 is increased, a pressure loss of the partition plate 130 that retains a dissolving liquid may be increased so as to rapidly decrease a flow volume of a discharged gas that is introduced into a flow path FP of the duct 110 by the gas introduction unit 150. In such a case, a flow volume of outside air that is incorporated from the plurality of outside air inlets 163 into the gas discharge unit 160 is decreased, so that it is possible to reduce or prevent a decrease in a flow volume of a discharged gas that is introduced into a flow path FP of the duct 110 by the gas introduction unit 150. Thereby, it is possible to reduce or prevent a pressure variation in a processing unit 16 that is associated with a decrease in a flow volume of an exhaust gas.

In a case where processes at steps S132, S134, S135 are ended, the controller 18 returns a process to step S131 and repeats processes at steps S131 to S135.

As described above, a gas processing device (for example, a gas processing device 100) according to a second embodiment includes a plurality of outside air inlets (for example, a plurality of outside air inlets 163) and a plurality of on-off valves (for example, on-off valves 164). The plurality of outside air inlets are provided on an upstream side of a changing unit (for example, a blower 170) of a gas discharge unit (for example, a gas discharge unit 160) and are capable of incorporating outside air. The plurality of on-off valves are respectively provided on the plurality of outside air inlets. Then, a controller 18 executes a process that regulates a flow volume of a dissolving liquid while maintaining a rotational speed of a fan in the changing part at a constant level. Furthermore, the controller 18 controls, when executing a process that regulates a flow volume of the dissolving liquid, opening/closing of the plurality of on-off valves separately depending on a flow volume of the dissolving liquid, so as to change a flow volume of outside air that is incorporated from the plurality of outside air inlets to the gas discharge unit. Thereby, in a gas processing device according to a second embodiment, it is possible to reduce or prevent a pressure variation in a processing unit (for example, a processing unit 16).

Variation(s)

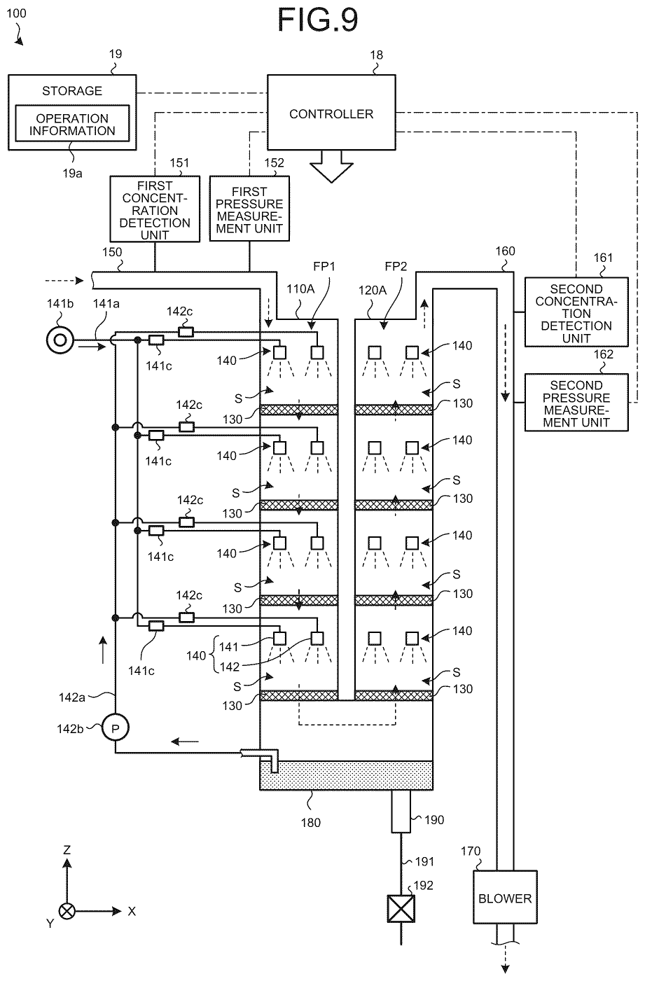

Although a case where the gas processing device 100 includes one duct 110 has been explained as an example in a first embodiment as described above, a number of a duct(s) that is/are included in the gas processing device 100 is not limited to one. For example, the gas processing device 100 may include two ducts as illustrated in FIG. 9.

FIG. 9 is a diagram that illustrates a configuration of a gas processing device 100 according to a variation of a first embodiment. Additionally, in FIG. 9, a flow of a discharged gas is represented by a dashed arrow and a flow of a dissolving liquid is represented by a solid arrow, similarly to FIG. 4. Furthermore, in FIG. 9, a part that is identical to that in FIG. 4 will be provided with an identical sign.

As illustrated in FIG. 9, the gas processing device 100 according to a variation includes a first duct 110A and a second duct 120A, instead of a duct 110 as illustrated in FIG. 4.

The first duct 110A has a first flow path FP1 in an inside thereof and the second duct 120A has a second flow path FP2 in an inside thereof. The first duct 110A and the second duct 120A are arranged so as to extend in upward and downward directions (directions of a Z-axis). Shapes of the first duct 110A and the second duct 120A may be, for example, any shape such as a circularly cylindrical shape and/or a square pipe shape.

A gas introduction unit 150 connects an upstream side collective exhaust pipe 55a (see FIG. 3) that is positioned on an upstream side of the gas processing device 100 in a collective exhaust pipe 55 and the first duct 110A, so as to introduce a discharged gas that flows through the upstream side collective exhaust pipe 55a into a first flow path FP1. Furthermore, a gas discharge unit 160 connects a downstream side collective exhaust pipe 55b (see FIG. 3) that is positioned on a downstream side of the gas processing device 100 in the collective exhaust pipe 55 and the second duct 120A, discharges a discharged gas that passes through a second flow path FP2 from the second duct 120A, and sends it to the downstream side collective exhaust pipe 55b. A lower end side of the first duct 110A, that is, a bottom part of a first flow path FP1, and a lower end side of the second duct 120A, that is, a bottom part of a second flow path FP2, are connected through a storage tank 180.

Specifically, the gas introduction unit 150 is connected to an upper end side of the first duct 110A and introduces a discharged gas from an upper end side of the first duct 110A (that is, a top part of a first flow path FP1) into a first flow path FP1. Furthermore, the gas discharge unit 160 is connected to an upper end side of the second duct 120A and discharges a discharged gas from an upper end side of the second duct 120A (that is, a top part of a second flow path FP2) to the downstream side collective exhaust pipe 55b. Therefore, a flow of a discharged gas from an upper side toward a lower side is formed on a first flow path FP1, a flow of a discharged gas from a bottom part of such a first flow path FP1 toward a bottom part of a second flow path FP2 is formed on the storage tank 180, and a flow of a discharged gas from a lower side toward an upper side is formed on such a second flow path FP2.

A partition plate 130 is arranged on each of a first flow path FP1 of the first duct 110A and a second flow path FP2 of the second duct 120A. The partition plate 130 partitions each of a first flow path FP1 and a second flow path FP2 into a plurality of spaces S that are adjacent to one another in upward and downward directions.

The partition plate 130 is attached to a plurality of attachment positions that are capable of adjusting sizes of a plurality of spaces S of each of a first flow path FP1 and a second flow path FP2 so as to be attachable and detachable. For example, a plurality of rails that extend in horizontal directions are formed on a first flow path FP1 and a second flow path FP2 at a regular interval(s) in upward and downward directions, and the partition plate 130 is attached to a desired rail among a plurality of rails of a first flow path FP1 and a second flow path FP2 so as to be attachable and detachable. As the partition plate 130 is attached to all rails of a first flow path FP1 and a second flow path FP2, sizes of a plurality of spaces S are identical to one another. As the partition plate 130 is detached from some rails among all rails, it is possible to increase sizes of some spaces S. Sizes of a plurality of spaces S may be identical to or different from one another between the first duct 110A and the second duct 120A. Furthermore, sizes of a plurality of spaces S may be identical to or different from one another in the first duct 110A or the second duct 120A.

A liquid supply unit 140 has a first liquid supply unit 141 and a second liquid supply unit 142. Additionally, although FIG. 9 illustrates only a supply system for a dissolving liquid on a side of the first duct 110A (a supply pipe 141a, a dissolving liquid supply source 141b, and a supply instrument group 141c) for explanatory convenience, a supply system for a dissolving liquid on a side of the second duct 120A is also similar to such a supply system for a dissolving liquid on a side of the first duct 110A. Furthermore, although FIG. 9 illustrates only a supply system for a circulating liquid on a side of the first duct 110A (a circulating liquid pipe 142a and a pump 142b) for explanatory convenience, a supply system for a circulating liquid on a side of the second duct 120A is also similar to such a supply system for a circulating liquid on a side of the first duct 110A.

The liquid supply unit 140 supplies a dissolving liquid from an upstream side of a first flow path FP1 toward the partition plate 130 on a lower side inside the first duct 110A, and supplies a dissolving liquid from a downstream side of a second flow path FP2 toward the partition plate 130 on a lower side inside the second duct 120A. A dissolving liquid that is supplied inside the first duct 110A and a dissolving liquid that is supplied inside the second duct 120A are identical types of liquids.

The storage tank 180 connects a downstream side of a first flow path FP1 of the first duct 110A and an upstream side of a second flow path FP2 of the second duct 120A, and stores a dissolving liquid that falls from the partition plate 130.

A controller 18 of the gas processing device 100 according to a variation executes a flow volume regulation process, based on operation information 19a and a detection result of a first concentration detection unit 151 (or a second concentration detection unit 161), similarly to the gas processing device 100 according to a first embodiment. Thereby, it is possible to reduce an amount of a used dissolving liquid.

Another/Other Variation(s)

In each embodiment as described above, the controller 18 may start a flow volume regulation process for a dissolving liquid, depending on a request signal from another device that is different from the substrate processing system 1. Thereby, it is possible to set a timing of a start of a flow volume regulation process freely, by using, for example, another device in a factory where the substrate processing system 1 is installed therein.

It should be considered that an embodiment(s) that is/are disclosed herein is/are not limitative but is/are illustrative in all aspects. Indeed, it is possible to implement an embodiment(s) as described above in a wide variety of modes. Furthermore, an embodiment(s) as described above may be omitted, substituted, and/or modified in a wide variety of modes without departing from an appended claim(s) and an essence thereof.

According to the present disclosure, an advantageous effect is provided in such a manner that it is possible to reduce an amount of a used dissolving liquid.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing apparatus, comprising:
a plurality of processing units that process a substrate by using a chemical product;
an exhaust route where a gas that is discharged from the plurality of processing units passes and flows therethrough;
a gas processing device that is provided on the exhaust route and eliminates a target component that is included in the gas that passes and flows through the exhaust route from the gas; and
a controller that controls the plurality of processing units and the gas processing device, wherein
the gas processing device includes:
a duct that has a flow path where the gas passes therethrough in an inside thereof;
a partition plate that partitions the flow path into a plurality of spaces where the partition plate is formed of a porous material that is capable of penetrating the gas and is capable of retaining a liquid;
a liquid supply unit that supplies a dissolving liquid that is capable of dissolving the target component that is included in the gas to the partition plate; and
a concentration detection unit that detects a concentration of the target component that is included in the gas, and
the controller regulates a flow volume of the dissolving liquid that is supplied from the liquid supply unit to the partition plate, based on at least one of operation information that indicates operation states of the plurality of processing units and a detection result of the concentration detection unit.

2. The substrate processing apparatus according to claim 1, wherein
the gas processing device further includes a storage tank that stores the dissolving liquid that falls from the partition plate,
the liquid supply unit has:
a first liquid supply unit that supplies the dissolving liquid that is supplied from a dissolving liquid supply source to the partition plate; and
a second liquid supply unit that supplies a circulating liquid that is obtained by circulating the dissolving liquid that is stored in the storage tank though a circulation route to the partition plate, and
the controller regulates a flow volume of the dissolving liquid that is supplied from the first liquid supply unit to the partition plate and a flow volume of the circulating liquid that is supplied from the second liquid supply unit to the partition plate, based on at least one of the operation information and the detection result of the concentration detection unit.

3. The substrate processing apparatus according to claim 2, wherein
the operation information is information that includes an operation time period when one of the processing units is operated and a non-operation time period when none of the processing units is operated, and
the controller maintains a flow volume of the dissolving liquid that is supplied from the first liquid supply unit to the partition plate at a predetermined maximum flow volume, in a case where a concentration that is detected by the concentration detection unit within the operation time period is greater than a predetermined first upper limit value.

4. The substrate processing apparatus according to claim 3, wherein
the controller maintains a flow volume of the circulating liquid that is supplied from the second liquid supply unit to the partition plate at a constant flow volume within the operation time period.

5. The substrate processing apparatus according to claim 3, wherein
the controller maintains a flow volume of the dissolving liquid that is supplied from the first liquid supply unit to the partition plate at a predetermined maximum flow volume, in a case where a concentration that is detected by the concentration detection unit within the non-operation time period is greater than a predetermined second upper limit value.

6. The substrate processing apparatus according to claim 5, wherein
the controller regulates a flow volume of the dissolving liquid that is supplied from the first liquid supply unit to the partition plate to be a flow volume that is dependent on a concentration that is detected by the concentration detection unit, in a case where a concentration that is detected by the concentration detection unit within the non-operation time period is the second upper limit value or less and is greater than a predetermined lower limit value.

7. The substrate processing apparatus according to claim 6, wherein
the controller stops supply of the dissolving liquid from the first liquid supply unit to the partition plate and supply of the circulating liquid from the second liquid supply unit to the partition plate, in a case where a concentration that is detected by the concentration detection unit within the non-operation time period is a predetermined lower limit value or less.

8. The substrate processing apparatus according to claim 1, wherein
the gas processing device further includes:
a gas discharge unit that discharges the gas from the flow path;
a changing unit that is provided on the gas discharge unit and rotates a fan to change a flow volume of the gas; and
a pressure measurement unit that measures a pressure of the gas, and
the controller adjusts a rotational speed of the fan in the changing unit based on a measurement result of the pressure measurement unit to change a flow volume of the gas.

9. The substrate processing apparatus according to claim 1, wherein
the gas processing device further includes:
a gas discharge unit that discharges the gas from the flow path;
a changing unit that is provided on the gas discharge unit and rotates a fan to change a flow volume of the gas;
a plurality of outside air inlets that are provided on an upstream side of the changing unit of the gas discharge unit and are capable of incorporating outside air; and
a plurality of on-off valves that are respectively provided on the plurality of outside air inlets, and
the controller executes a process that regulates a flow volume of the dissolving liquid while maintaining a rotational speed of the fan in the changing part at a constant level, and controls, when executing the process that regulates the flow volume of the dissolving liquid, opening/closing of the plurality of on-off valves separately depending on the flow volume of the dissolving liquid, to change a flow volume of outside air that is incorporated from the plurality of outside air inlets into the gas discharge unit.

10. The substrate processing apparatus according to claim 1, wherein
the controller starts the process that regulates the flow volume of the dissolving liquid that is supplied from the liquid supply unit to the partition plate, depending on a request signal from another device that is different from the substrate processing apparatus.

11. The substrate processing apparatus according to claim 1, wherein
a porous material that forms the partition plate is a porous ceramic(s).

12. A control method for a substrate processing apparatus that includes:
a plurality of processing units that process a substrate by using a chemical product;
an exhaust route where a gas that is discharged from the plurality of processing units passes and flows therethrough; and
a gas processing device that is provided on the exhaust route and eliminates a target component that is included in the gas that passes and flows through the exhaust route from the gas, wherein
the gas processing device includes:
a duct that has a flow path where the gas passes therethrough in an inside thereof;
a partition plate that partitions the flow path into a plurality of spaces where the partition plate is formed of a porous material that is capable of penetrating the gas and is capable of retaining a liquid;
a liquid supply unit that supplies a dissolving liquid that is capable of dissolving the target component that is included in the gas to the partition plate; and
a concentration detection unit that detects a concentration of the target component that is included in the gas, wherein
a flow volume of the dissolving liquid that is supplied from the liquid supply unit to the partition plate is regulated, based on at least one of operation information that indicates operation states of the plurality of processing units and a detection result of the concentration detection unit.
